(19) United States
(12) Patent Application Publication
(10) Pub. No.: US 2025/0273403 A1
(43) Pub. Date: Aug. 28, 2025

(54) CAPACITOR AND ELECTRONIC DEVICE

(71) Applicant: Industrial Technology Research Institute, Hsinchu (TW)

(72) Inventors: Tai-Jui Wang, Kaohsiung City (TW); Wei-Yen Chen, Taoyuan City (TW); Chieh-Wei Feng, Taoyuan City (TW)

(73) Assignee: Industrial Technology Research Institute, Hsinchu (TW)

(21) Appl. No.: 18/634,972

(22) Filed: Apr. 14, 2024

(30) Foreign Application Priority Data
Feb. 27, 2024 (TW) 113107046

(51) Int. Cl. H01G 4/33; H01G 4/08; H01G 4/14; H01G 4/224; H01G 4/252; H01L 25/16

(52) U.S. Cl. CPC H01G 4/33; H01G 4/08; H01G 4/14; H01G 4/224; H01G 4/252; H01L 25/16

(57) ABSTRACT

A capacitor including a first electrode, a second electrode, and a first capacitor dielectric layer is provided. The first capacitor dielectric layer is disposed between the first electrode and the second electrode. The first capacitor dielectric layer includes a first dielectric layer and a second dielectric layer, the first dielectric layer includes an inorganic dielectric layer, and the second dielectric layer includes an organic dielectric layer, wherein the first dielectric layer is located between the first electrode and the second dielectric layer, and the second dielectric layer is located between the first dielectric layer and the second electrode.

### CROSS-REFERENCE TO RELATED APPLICATION

This application claims the priority benefit of Taiwan application serial no. 113107046, filed on Feb. 27, 2024. The entirety of the above-mentioned patent application is hereby incorporated by reference herein and made a part of specification.

### TECHNICAL FIELD

The disclosure relates to a capacitor, and also relates to a capacitor in an electronic device.

### BACKGROUND

In existing techniques, the overall structure of passive elements, such as multi-layer ceramic capacitors (MLCC), is often too thick, making it difficult to miniaturize subsequent integrated circuit packaging. Therefore, techniques that integrate a passive element into the redistribution structure of the package structure via a thin film process have been proposed. Since the large-area panel-level redistribution process faces high dielectric loss due to poor flatness of the dielectric thin film, energy loss and heating issues occur in the capacitor, thereby reducing the overall performance of the passive element. Moreover, when the passive element is operated at a high frequency, the natural frequency of the capacitor stack is readily affected by the size thereof, causing the capacitance value to deviate from the original design. That is, the capacitance value of the capacitor is unstable, such as the issue of changing from capacitance to inductance.

### SUMMARY

An embodiment of the disclosure provides a capacitor and an electronic device having the capacitor.

In an embodiment of the disclosure, the capacitor includes a first electrode, a second electrode, and a first capacitor dielectric layer. The first capacitor dielectric layer is disposed between the first electrode and the second electrode. The first capacitor dielectric layer includes a first dielectric layer and a second dielectric layer, the first dielectric layer includes an inorganic dielectric layer, and the second dielectric layer includes an organic dielectric layer, wherein the first dielectric layer is located between the first electrode and the second dielectric layer, and the second dielectric layer is located between the first dielectric layer and the second electrode.

In another embodiment of the disclosure, an electronic device includes a substrate, a redistribution structure, a capacitor, and a chip. The redistribution structure is disposed on the substrate. The capacitor is electrically connected to the redistribution structure, wherein the capacitor includes a first electrode, a second electrode, and a first capacitor dielectric layer, the first capacitor dielectric layer is disposed between the first electrode and the second electrode, the first capacitor dielectric layer includes a first dielectric layer and a second dielectric layer, the first dielectric layer includes an inorganic dielectric layer, and the second dielectric layer includes an organic dielectric layer, wherein the first dielectric layer is located between the first electrode and the second dielectric layer, and the second dielectric layer is located between the first dielectric layer and the second electrode. The chip is disposed on the redistribution structure and electrically connected to the redistribution structure.

### BRIEF DESCRIPTION OF THE DRAWINGS

FIG. 1 is a schematic cross-sectional view of a capacitor according to the first embodiment of the disclosure.

FIG. 2 is a schematic cross-sectional view of a capacitor according to the second embodiment of the disclosure.

FIG. 3A is a schematic cross-sectional view of a capacitor according to the third embodiment of the disclosure.

FIG. 3B is another schematic cross-sectional view of a capacitor according to the third embodiment of the disclosure.

FIG. 4 is a schematic cross-sectional view of a capacitor according to the fourth embodiment of the disclosure.

FIG. 5 is a schematic cross-sectional view of an electronic device according to the fifth embodiment of the disclosure.

FIG. 6 is a schematic cross-sectional view of an electronic device according to the sixth embodiment of the disclosure.

FIG. 7 is a schematic cross-sectional view of an electronic device according to the seventh embodiment of the disclosure.

FIG. 8 is a schematic cross-sectional view of an electronic device according to the eighth embodiment of the disclosure.

FIG. 9 is a schematic cross-sectional view of an electronic device according to the ninth embodiment of the disclosure.

FIG. 10 is a schematic cross-sectional view of an electronic device according to the tenth embodiment of the disclosure.

### DESCRIPTION OF THE EMBODIMENTS

Embodiments are provided hereinafter and described in detail with reference to figures. However, the embodiments provided are not intended to limit the scope of the disclosure. In addition, the drawings are for illustration purposes and are not drawn to original scale. In order to facilitate understanding, the same elements are described with the same reference numerals in the following description. In addition, the terms “contain”, “include”, “have”, etc. used in the article are all open terms, meaning “containing but not limited to”. Furthermore, the directional terms mentioned in the article, such as “up”, “down”, etc., are used to refer to the direction of the drawings and are not used to limit the disclosure. In addition, the quantities and shapes mentioned in the specification are used to specifically illustrate the disclosure to facilitate understanding of the content thereof, but are not used to limit the disclosure.

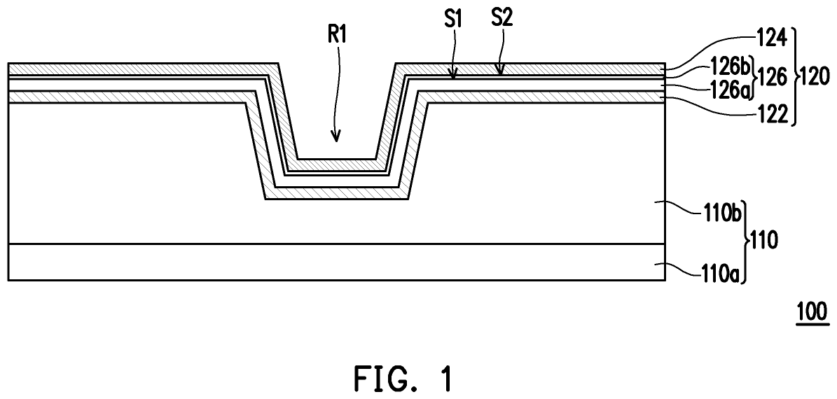

FIG. 1 is a schematic cross-sectional view of a capacitor according to the first embodiment of the disclosure. Referring to FIG. 1, a capacitor 100 of the present embodiment includes a substrate 110 and a capacitor stack 120 disposed on the substrate 110. The substrate 110 includes a first material layer 110a and a second material layer 110b disposed on the first material layer 110a. For example, the first material layer 110a of the substrate 110 includes glass, and the second material layer 110b of the substrate 110 includes an organic dielectric material. As shown in FIG. 1, the substrate 110 has a groove R1, the groove R1 in the substrate 110 is distributed in the second material layer 110b, and the capacitor stack 120 covers the bottom surface of the groove R1, the side surface of the groove R1, and the top surface of the second material layer 110b. In other words, the depth of the groove R1 is less than the thickness of the second material layer 110b. For example, the bottom area of the groove R1 is 20 microns×20 microns, and the depth of the groove R1 is between 10 microns and 20 microns.

The thin-film capacitor stack 120 includes a first electrode 122, a second electrode 124, and a first capacitor dielectric layer 126, wherein the first capacitor dielectric layer 126 is disposed between the first electrode 122 and the second electrode 124. The first capacitor dielectric layer 126 includes a first dielectric layer 126a and a second dielectric layer 126b, the first dielectric layer 126a includes an inorganic dielectric layer, the second dielectric layer 126b includes an organic dielectric layer, the first dielectric layer 126a is located between the first electrode 122 and the second dielectric layer 126b, and the second dielectric layer 126b is located between the first dielectric layer 126a and the second electrode 124. In addition, the thickness of the first dielectric layer 126a is between 180 nm and 220 nm, and the thickness of the second dielectric layer 126b is between 20 nm and 50 nm.

As shown in FIG. 1, the first electrode 122 is disposed on the substrate 110, and the first capacitor dielectric layer 126 and the second electrode 124 are stacked on the first electrode 122. Moreover, the first electrode 122, the first capacitor dielectric layer 126, and the second electrode 124 cover the bottom surface of the groove R1, the side surface of the groove R1, and the top surface of the second material layer 110b, and the first electrode 122 is in contact with the bottom surface of the groove R1, the side surface of the groove R1, and the top surface of the second material layer 110b.

In the present embodiment, the first dielectric layer 126a has a first surface S1, the first surface S1 of the first dielectric layer 126a is covered by the second dielectric layer 126b, and the first surface S1 of the first dielectric layer 126a is in contact with the second dielectric layer 126b; the second dielectric layer 126b has a second surface S2, the second surface S2 of the second dielectric layer 126b is covered by the second electrode 124, and the second surface S2 of the second dielectric layer 126b is in contact with the second electrode 124, wherein the roughness of the first surface S1 of the first dielectric layer 126a is greater than the roughness of the second surface S2 of the second dielectric layer 126b. In other words, the interface roughness between the first dielectric layer 126a and the second dielectric layer 126b is greater than the interface roughness between the second electrode 124 and the second dielectric layer 126b. For example, the roughness of the first surface S1 of the first dielectric layer 126a is between 30 nanometers and 90 nanometers, and the roughness of the second surface S2 of the second dielectric layer 126b is between 10 nanometers and 40 nanometers. Since the second dielectric layer 126b made of organic material has better step coverage, the second dielectric layer 126b covering the first surface S1 of the first dielectric layer 126a with higher roughness may provide the second surface S2 with lower roughness.

In the present embodiment, the distribution area of the capacitor stack 120 (i.e., the first electrode 122, the second electrode 124, and the first capacitor dielectric layer 126) in the capacitor 100 is less than or equal to 50 microns×50 microns. When the distribution area of the capacitor 100 is controlled within the range of 50 microns×50 microns, the natural frequency of the capacitor 100 may be well controlled during high-frequency operation, and the control of the distribution area of the capacitor 100 may alleviate the dielectric loss issue during high-speed transmission caused by poor flatness of a large-area dielectric thin film.

It is worth noting that the capacitance value provided by the thin-film capacitor stack 120 may be adjusted by the included angle between the sidewall and the bottom of the groove R1. In other words, the capacitance value provided by the thin-film capacitor stack 120 may be adjusted via the slope of the sidewall of the groove R1 and the depth of the groove R1. In some embodiments, the distribution area of the capacitor stack 120 covering the groove R1 is preferably between 22.5 microns×22.5 microns and 35 microns×35 microns. In some other embodiments, the groove R1 formed in the substrate 110 may be omitted. In other words, the capacitor stack 120 may be directly formed on the surface of the substrate 110.

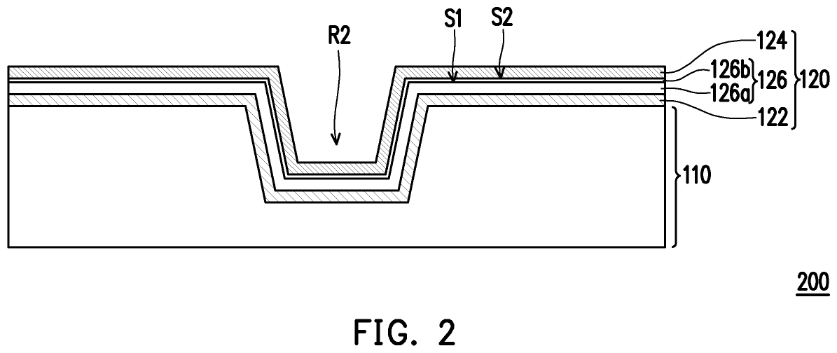

FIG. 2 is a schematic cross-sectional view of a capacitor according to the second embodiment of the disclosure. Please refer to FIG. 1 and FIG. 2. A capacitor 200 of the present embodiment is similar to the capacitor 100 of the first embodiment, but the main difference between the two is: the substrate 110 in the present embodiment is a glass substrate, and a groove R2 is distributed in the glass substrate 110. In addition, the groove R2 does not penetrate the substrate 110. In other words, the depth of the groove R2 is less than the thickness of the substrate 110. For example, the bottom area of the groove R2 is 20 microns×20 microns, and the depth of the groove R2 is between 10 microns and 20 microns.

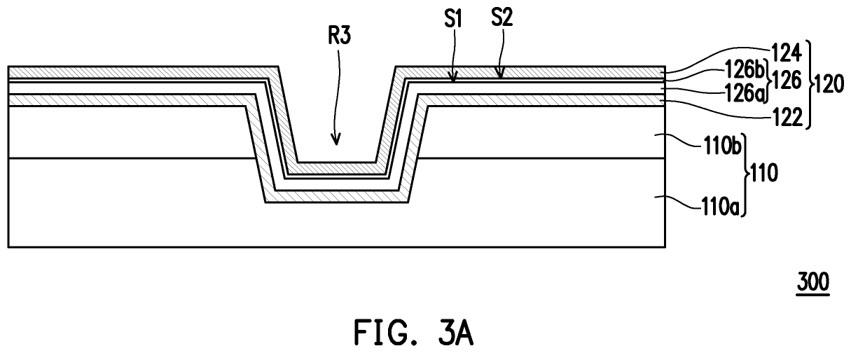

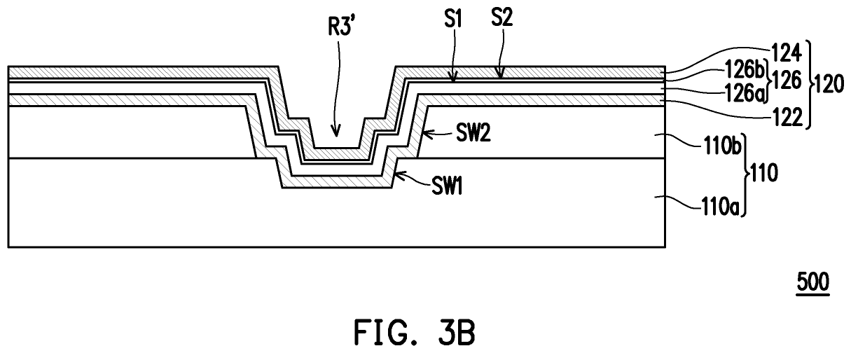

FIG. 3A is a schematic cross-sectional view of a capacitor according to the third embodiment of the disclosure. Please refer to FIG. 1 and FIG. 3A. A capacitor 300 of the present embodiment is similar to the capacitor 100 of the first embodiment, but the main difference between the two is: a groove R3 in the present embodiment penetrates the second material layer 110b and is extended into a portion of the first material layer 110a. In addition, the groove R3 does not penetrate the first material layer 110a of the substrate 110. In other words, the depth of the groove R3 is greater than the thickness of the second material layer 110b, and the depth of the groove R3 is less than the thickness of the substrate 110. For example, the bottom area of the groove R3 is 20 microns×20 microns, and the depth of the groove R3 is between 10 microns and 20 microns.

As shown in FIG. 3A, the first electrode 122, the first capacitor dielectric layer 126, and the second electrode 124 cover the bottom surface of the groove R3, the side surface of the groove R3, and the top surface of the second material layer 110b. Moreover, the bottom and the lower half sidewall of the groove R3 may be defined by the first material layer 110a, the upper half sidewall of the groove R3 may be defined by the second material layer 110b, and the first electrode 122 is in contact with the first material layer 110a and the second material layer 110b at the same time.

FIG. 3B is another schematic cross-sectional view of a capacitor according to the third embodiment of the disclosure. Please refer to FIG. 3A and FIG. 3B. A capacitor 500 shown in FIG. 3B is similar to the capacitor 300 shown in FIG. 3A, but the main difference between the two is: in the present embodiment, a groove R3′ penetrating the second material layer 110b and extended to a portion of the first material layer 110a has a stepped sidewall. A lower half sidewall SW1 and an upper half sidewall SW2 of the groove R3′, wherein the first material layer 110a defines the lower half sidewall SW1 of the groove R3′, the second material layer 110b defines the upper half sidewall SW2 of the groove R3′, and since the materials of the first material layer 110a and the second material layer 110b are different, the slope of the lower half sidewall SW1 is different from the slope of the upper half sidewall SW2. In some embodiments, the slope of the lower half sidewall SW1 is greater than the slope of the upper half sidewall SW2. In some other embodiments, the slope of the lower half sidewall SW1 is less than the slope of the upper half sidewall SW2. It is worth noting that the difference in slope between the lower half sidewall SW1 and the upper half sidewall SW2 mainly depends on the material selection of the first material layer 110a and the second material layer 110b. For example, the bottom area of the groove R3′ is 20 microns×20 microns, and the depth of the groove R3′ is between 10 microns and 20 microns. As shown in FIG. 3B, the first electrode 122, the first capacitor dielectric layer 126, and the second electrode 124 cover the bottom surface of the groove R3′, the partial top surface of the first material layer 110a (i.e., the area connected between the side surfaces SW1 and SW2), the side surfaces SW1 and SW2 of the groove R3′, and the top surface of the second material layer 110b.

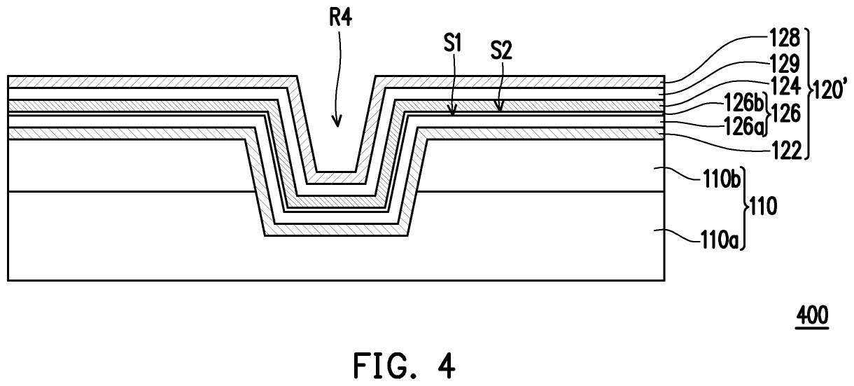

FIG. 4 is a schematic cross-sectional view of a capacitor according to the fourth embodiment of the disclosure. Please refer to FIG. 3A and FIG. 4. A capacitor 400 of the present embodiment is similar to the capacitor 300 of the third embodiment. The main difference between the two is a capacitor stack 120′ covering a groove R4. As shown in FIG. 4, in addition to the first electrode 122, the second electrode 124, and the first capacitor dielectric layer 126, the capacitor stack 120′ further includes a third electrode 128 and a second capacitor dielectric layer 129. The second capacitor dielectric layer 129 is disposed on the second electrode 124, and the second capacitor dielectric layer 129 is located between the second electrode 124 and the third electrode 128. Moreover, the third electrode 128 and the second capacitor dielectric layer 129 in the capacitor stack 120′ of the present embodiment may also be applied to the capacitor 100 shown in FIG. 1 and the capacitor 200 shown in FIG. 2.

In the present embodiment, the second capacitor dielectric layer 129 has a single-layer thin-film structure, and the material of the second capacitor dielectric layer 129 may be the same as or different from the material of the first dielectric layer 126a. For example, the material of the second capacitor dielectric layer 129 includes an inorganic dielectric material that is the same as or different from the material of the first dielectric layer 126a.

In other embodiments, the second capacitor dielectric layer 129 may have the same stacked thin-film structure as the first capacitor dielectric layer 126. For example, the second capacitor dielectric layer 129 may include an inorganic dielectric layer and an organic dielectric layer, the inorganic dielectric layer is located between the second electrode 124 and the organic dielectric layer, and the organic dielectric layer is located between the inorganic dielectric layer and the third electrode 128.

FIG. 5 is a schematic cross-sectional view of an electronic device according to the fifth embodiment of the disclosure.

Referring to FIG. 5, an electronic device P1 of the present embodiment includes a substrate 510, a redistribution structure 520, a chip 530, and a capacitor 540. For example, the substrate 510 includes a glass substrate. The redistribution structure 520 is disposed on the surface of the substrate 510. The chip 530 is disposed on the redistribution structure 520 and electrically connected to the redistribution structure 520.

In addition, the capacitor 540 is disposed on the surface of the substrate 510 and embedded or buried in the redistribution structure 520. In the present embodiment, before the capacitor 540 is disposed and the redistribution structure 520 is formed, a wire 512 (e.g., metal wire) may be formed on the surface of the substrate 510, wherein the capacitor 540 is disposed on the wire 512, and the capacitor 540 is electrically connected to the wire 512.

In the present embodiment, the redistribution structure 520 includes a plurality of dielectric layers 522 and a plurality of redistribution layers 524 alternately stacked, wherein the plurality of dielectric layers 522 include a bottom-most dielectric layer 522a covering the substrate 510 and the capacitor 540 and a topmost dielectric layer 522b disposed on the bottom-most dielectric layer 522a, and the plurality of redistribution layers 524 include a bottom-most redistribution layer 524a disposed on the bottom-most dielectric layer 522a and electrically connected to the wire 512 and a topmost redistribution layer 524b disposed on the bottom-most redistribution layer 524a. It is worth noting that the individual quantities of the dielectric layer 522 and the redistribution layer 524 in the redistribution structure 520 are not limited to two layers. In other words, there may be other dielectric layers between the bottom-most dielectric layer 522a and the topmost dielectric layer 522b, and there may be other redistribution layers between the bottom-most redistribution layer 524a and the topmost redistribution layer 524b. As shown in FIG. 5, the wire 512 and the capacitor 540 disposed on the surface of the substrate 510 are in contact with the bottom-most dielectric layer 522a in the plurality of dielectric layers 522, and the capacitor 540 may be electrically connected to the bottom-most redistribution layer 524a via the wire 512 formed on the substrate 510. Here, the architecture of the capacitor 540 may be the architecture of the capacitor 100, 200, 300, 400, or 500 shown in FIG. 1, FIG. 2, FIG. 3A, FIG. 3B, or FIG. 4. Since the thickness of the capacitor 540 may be controlled in the order of hundreds of nanometers to microns, and the capacitor 540 is embedded or buried in the redistribution structure 520, the overall thickness of the electronic device P1 is not affected by the thickness of the capacitor 540 and may not be further reduced.

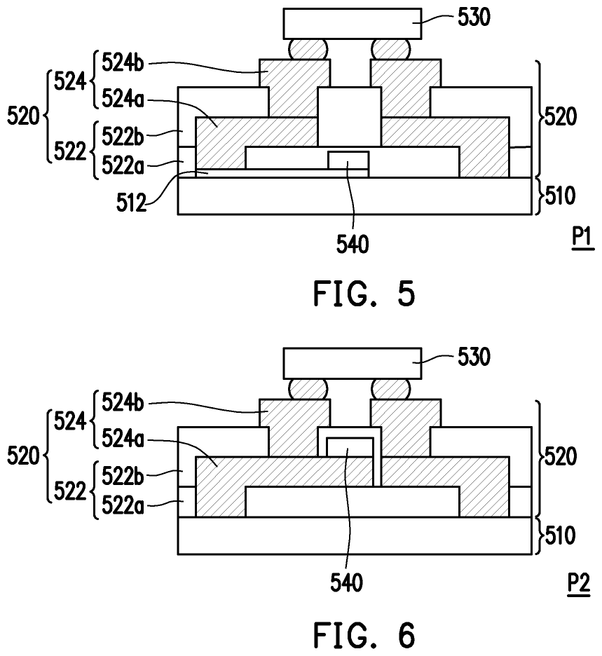

FIG. 6 is a schematic cross-sectional view of an electronic device according to the sixth embodiment of the disclosure.

Please refer to FIG. 5 and FIG. 6. An electronic device P2 of the present embodiment is similar to the electronic device P1 of the fifth embodiment. The main difference between the two is the location of the capacitor 540. As shown in FIG. 6, the redistribution structure 520 includes the plurality of dielectric layers 522 and the plurality of redistribution layers 524 alternately stacked, wherein the plurality of dielectric layers 522 include the bottom-most dielectric layer 522a covering the substrate 510 and the topmost dielectric layer 522b disposed on the bottom-most dielectric layer 522a, the plurality of redistribution layers 524 include the bottom-most redistribution layer 524a disposed on the bottom-most dielectric layer 522a and the topmost redistribution layer 524b disposed on the topmost dielectric layer 522b, and the topmost redistribution layer 524b is electrically connected to the bottom-most redistribution layer 524a. It is worth noting that the individual quantities of the dielectric layer 522 and the redistribution layer 524 in the redistribution structure 520 are not limited to two layers. In other words, there may be other dielectric layers between the bottom-most dielectric layer 522a and the topmost dielectric layer 522b, and there may be other redistribution layers between the bottom-most redistribution layer 524a and the topmost redistribution layer 524b. In the present embodiment, the capacitor 540 is not disposed on the surface of the substrate 510. The capacitor 540 is disposed on the bottom-most redistribution layer 524a and electrically connected to the bottom-most redistribution layer 524a. Additionally, the capacitor 540 is covered by the topmost dielectric layer 522b in the redistribution structure 520.

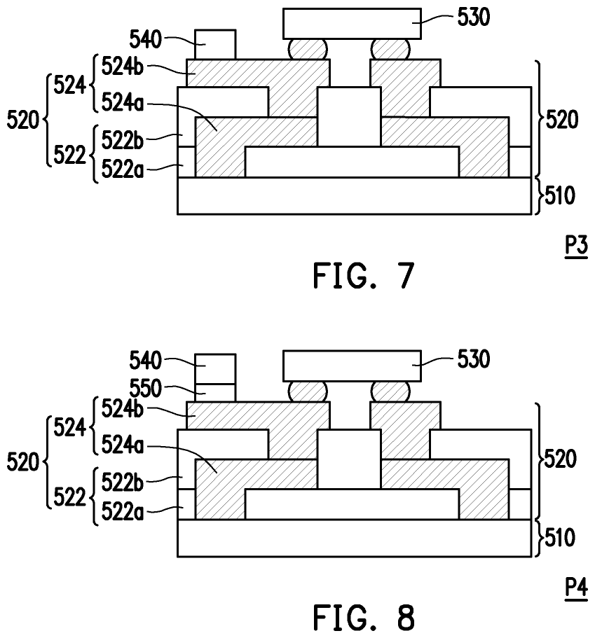

FIG. 7 is a schematic cross-sectional view of an electronic device according to the seventh embodiment of the disclosure. Please refer to FIG. 5 and FIG. 7. An electronic device P3 of the present embodiment is similar to the electronic device P1 of the fifth embodiment. The main difference between the two is the location of the capacitor 540. As shown in FIG. 7, the redistribution structure 520 includes the plurality of dielectric layers 522 and the plurality of redistribution layers 524 alternately stacked, wherein the plurality of dielectric layers 522 include the bottom-most dielectric layer 522a covering the substrate 510 and the topmost dielectric layer 522b disposed on the bottom-most dielectric layer 522a, the plurality of redistribution layers 524 include the bottom-most redistribution layer 524a disposed on the bottom-most dielectric layer 522a and the topmost redistribution layer 524b disposed on the topmost dielectric layer 522b, and the topmost redistribution layer 524b is electrically connected to the bottom-most redistribution layer 524a. It is worth noting that the individual quantities of the dielectric layer 522 and the redistribution layer 524 in the redistribution structure 520 are not limited to two layers. In other words, there may be other dielectric layers between the bottom-most dielectric layer 522a and the topmost dielectric layer 522b, and there may be other redistribution layers between the bottom-most redistribution layer 524a and the topmost redistribution layer 524b. The capacitor 540 is not disposed on the surface of the substrate 510. The capacitor 540 is disposed on the surface of the redistribution structure 520, and the capacitor 540 is electrically connected to the topmost redistribution layer 524b. In the present embodiment, the capacitor 540 is a surface mount-type passive element (capacitor).

FIG. 8 is a schematic cross-sectional view of an electronic device according to the eighth embodiment of the disclosure. Please refer to FIG. 7 and FIG. 8. An electronic device P4 of the present embodiment is similar to the electronic device P3 of the seventh embodiment. The main difference between the two is the electrical connection method between the capacitor 540 and the redistribution structure 520. As shown in FIG. 8, the capacitor 540 is disposed on the surface of the redistribution structure 520, and the capacitor 540 is electrically connected to the topmost redistribution layer via a bonding structure 550. The bonding structure 550 includes a metal material, such as Cu.

It is worth noting that the quantity of the capacitor 540 in the electronic devices P1, P2, P3, and P4 is not limited to one. There may be a plurality of the capacitor 540 in the electronic devices P1, P2, P3, and P4, and the plurality of the capacitor 540 (the capacitors 100, 200, 300, 400, 500 shown in FIG. 1, FIG. 2, FIG. 3A, FIG. 3B, and FIG. 4) and various setting positions (such as the setting positions shown in FIG. 5 to FIG. 8) are adopted in the electronic device.

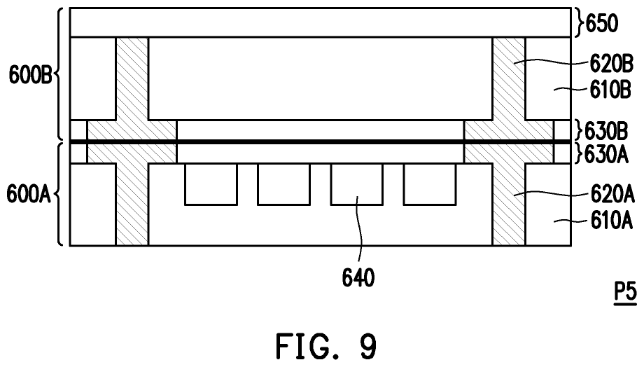

FIG. 9 is a schematic cross-sectional view of an electronic device according to the ninth embodiment of the disclosure. Referring to FIG. 9, an electronic device P5 of the present embodiment includes a lower electronic device 600A and an upper electronic device 600B disposed on the lower electronic device 600A. The lower electronic device 600A includes a first substrate 610A, a first conductive via 620A penetrating the first substrate 610A, a capacitor 640 embedded in the first substrate 610A, and a first bonding structure 630A, wherein the first bonding structure 630A covers the first substrate 610A, the first conductive via 620A, and the capacitor 640, and the first bonding structure 630A is electrically connected to the first conductive via 620A and the capacitor 640. The upper electronic device 600B includes a second substrate 610B, a second conductive via 620B penetrating the second substrate 610B, and a redistribution structure 650, wherein a second bonding structure 630B covers the second substrate 610B and the second conductive via 620B, and the second bonding structure 630B is electrically connected to the second conductive via 620B. Moreover, the redistribution structure 650 covers the second substrate 610B and the second conductive via 620B, and the redistribution structure 650 is electrically connected to the second bonding structure 630B via the second conductive via 620B.

As shown in FIG. 9, the lower electronic device 600A and the upper electronic device 600B may be electrically connected to each other via the first bonding structure 630A and the second bonding structure 630B. The capacitor 640 may be electrically connected to the redistribution structure 650 via the first bonding structure 630A, the second bonding structure 630B, and the second conductive via 620B. The first bonding structure 630A and the second bonding structure 630B include a metal material, such as Cu.

Here, the architecture of the capacitor 640 in the electronic device P5 may be the architecture of the capacitor 100, 200, 300, 400, or 500 shown in FIG. 1, FIG. 2, FIG. 3A, FIG. 3B, or FIG. 4.

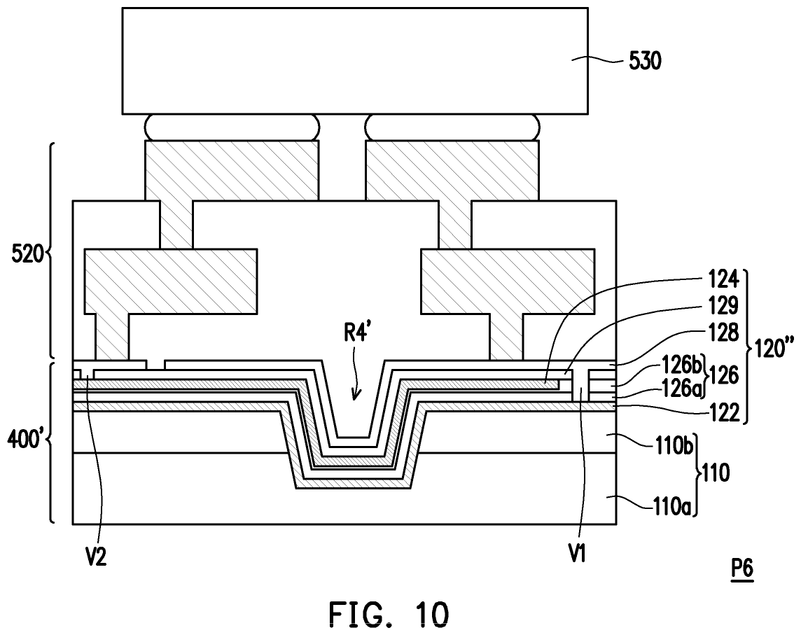

FIG. 10 is a schematic cross-sectional view of an electronic device according to the tenth embodiment of the disclosure. Please refer to FIG. 4 and FIG. 10. A capacitor 400′ in an electronic device P6 of the present embodiment is similar to the capacitor 400 of the fourth embodiment. The main difference between the two is that the capacitor 400′ in the present embodiment further includes a conductive via V1 and a conductive via V2, wherein the first electrode 122 is electrically connected to the first portion of the third electrode 128 (for example, the right portion of the third electrode 128 in FIG. 10) via the conductive via V1, the second electrode 124 is electrically connected to the second portion of the third electrode 128 (for example, the left portion of the third electrode 128 in FIG. 10) via the conductive via V2, and the first portion of the third electrode 128 is electrically insulated from the second portion of the third electrode 128. As shown in FIG. 10, the electronic device P6 of the present embodiment includes the capacitor 400′, the redistribution structure 520, and the chip 530, wherein the redistribution structure 520 is disposed on the capacitor 400′ and electrically connected to the capacitor 400′, and the chip 530 is disposed on the redistribution structure 520 and electrically connected to the capacitor 400′ via the redistribution structure 520. For example, the first portion of the third electrode 128 electrically connected to the first electrode 122 is electrically connected to one terminal of the chip 530 via the wire in the redistribution structure 520, and the second portion of the third electrode 128 electrically connected to the second electrode 124 is electrically connected to another terminal of the chip 530 via other wires in the redistribution structure 520. As shown in FIG. 10, the dielectric layer in the redistribution structure 520 may be filled in the groove R4′ of the capacitor 400′.

In the embodiments of the disclosure, the capacitor dielectric layer having the inorganic dielectric layer and the organic dielectric layer may effectively control the natural frequency of the capacitor during high-frequency operation, thus alleviating the dielectric loss issue during high-speed transmission caused by poor flatness of the dielectric thin film.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A capacitor, comprising:
a first electrode;
a second electrode; and
a first capacitor dielectric layer disposed between the first electrode and the second electrode, wherein the first capacitor dielectric layer comprises a first dielectric layer and a second dielectric layer, the first dielectric layer comprises an inorganic dielectric layer, and the second dielectric layer comprises an organic dielectric layer, wherein the first dielectric layer is located between the first electrode and the second dielectric layer, and the second dielectric layer is located between the first dielectric layer and the second electrode.

2. The capacitor of claim 1, wherein the first dielectric layer has a first surface, the first surface is in contact with the second dielectric layer, the second dielectric layer has a second surface, the second surface is in contact with the second electrode, and a roughness of the first surface is greater than a roughness of the second surface.

3. The capacitor of claim 1, wherein a distribution area of the first electrode, the second electrode, and the first capacitor dielectric layer is less than or equal to 50 microns×50 microns.

4. The capacitor of claim 1, further comprising:
a substrate, wherein the first electrode is disposed on the substrate, and the first capacitor dielectric layer and the second electrode are stacked on the first electrode.

5. The capacitor of claim 4, wherein the substrate has a groove, and the first electrode, the first capacitor dielectric layer, and the second electrode cover the groove.

6. The capacitor of claim 4, wherein the substrate comprises:
a first material layer; and
a second material layer disposed on the first material layer.

7. The capacitor of claim 6, wherein the substrate has a groove, the groove penetrates the second material layer and is extended into a portion of the first material layer, and the first electrode, the first capacitor dielectric layer, and the second electrode cover the groove.

8. The capacitor of claim 6, wherein the substrate has a groove, the groove is distributed in the second material layer, and the first electrode, the first capacitor dielectric layer, and the second electrode cover the groove.

9. The capacitor of claim 1, further comprising:
a third electrode; and
a second capacitor dielectric layer, wherein the second capacitor dielectric layer is disposed on the second electrode, and the second capacitor dielectric layer is located between the second electrode and the third electrode.

10. An electronic device, comprising:
a substrate;
a redistribution structure disposed on the substrate;
a capacitor electrically connected to the redistribution structure, wherein the capacitor comprises a first electrode, a second electrode, and a first capacitor dielectric layer, the first capacitor dielectric layer is disposed between the first electrode and the second electrode, the first capacitor dielectric layer comprises a first dielectric layer and a second dielectric layer, the first dielectric layer comprises an inorganic dielectric layer, and the second dielectric layer comprises an organic dielectric layer, wherein the first dielectric layer is located between the first electrode and the second dielectric layer, and the second dielectric layer is located between the first dielectric layer and the second electrode; and
a chip disposed on the redistribution structure and electrically connected to the redistribution structure.

11. The electronic device of claim 10, wherein the first dielectric layer has a first surface, the first surface is in contact with the second dielectric layer, the second dielectric layer has a second surface, the second surface is in contact with the second electrode, and a roughness of the first surface is greater than a roughness of the second surface.

12. The electronic device of claim 10, wherein a distribution area of the first electrode, the second electrode, and the first capacitor dielectric layer is less than or equal to 50 microns×50 microns.

13. The electronic device of claim 10, wherein the capacitor further comprises:
a substrate, wherein the first electrode is disposed on the substrate, and the first capacitor dielectric layer and the second electrode are stacked on the first electrode.

14. The electronic device of claim 13, wherein the substrate has a groove, and the first electrode, the first capacitor dielectric layer, and the second electrode cover the groove.

15. The electronic device of claim 13, wherein the substrate comprises:
a first material layer; and
a second material layer disposed on the first material layer.

16. The electronic device of claim 15, wherein the substrate has a groove, the groove penetrates the second material layer and is extended into a portion of the first material layer, and the first electrode, the first capacitor dielectric layer, and the second electrode cover the groove.

17. The electronic device of claim 15, wherein the substrate has a groove, the groove is distributed in the second material layer, and the first electrode, the first capacitor dielectric layer, and the second electrode cover the groove.

18. The electronic device of claim 10, wherein the capacitor further comprises:
a third electrode; and
a second capacitor dielectric layer, wherein the second capacitor dielectric layer is disposed on the second electrode, and the second capacitor dielectric layer is located between the second electrode and the third electrode.

19. The electronic device of claim 10, wherein the capacitor is embedded in the redistribution structure.

20. The electronic device of claim 10, wherein the capacitor is disposed on the redistribution structure.
